(19) United States
(12) Patent Application Publication
(10) Pub. No.: US 2002/0142619 A1
(43) Pub. Date: Oct. 3, 2002

(54) Solution composition and process for etching silicon

(75) Inventors: Alexis Grabbe, St. Charles, MO (US); Thomas E. Doane, St. Charles, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/038,550

(22) Filed: Jan. 4, 2002

Related U.S. Application Data
(60) Provisional application No. 60/280,680, filed on Mar. 30, 2001.

(51) Int. Cl. H01L 21/302; H01L 21/461

(52) U.S. Cl. 438/753

(57) ABSTRACT

A process for etching a silicon wafer is disclosed. The process comprises oxidizing silicon with permanganate ions and stripping the silicon oxide with hydrofluoric acid, in the presence of a non-oxidizable acid and typically a surfactant. The present process affords a means to more consistently obtain a silicon wafer having improved gloss or smoothness, while minimizing both the amount of silicon removed from the wafer surface and the cost of the etching process.

### CROSS-REFERENCE TO RELATED APPLICATION

This application claims the benefit of U.S. Provisional Application No. 60/280,680, filed Mar. 30, 2001.

### FIELD OF THE INVENTION

The process of the present invention generally relates to the etching of semiconductor wafers. More particularly, the present invention relates to a process for etching a silicon wafer by oxidizing silicon with permanganate ions and stripping the silicon oxide with hydrofluoric acid, in the presence of a non-oxidizable acid and typically a surfactant. The process provides a means to consistently produce semiconductor wafer surfaces having a specular appearance.

### BACKGROUND OF THE INVENTION

Semiconductor wafers, such as silicon wafers, are typically obtained from single crystal silicon ingots by a process which includes a number of steps. First, the single crystal silicon ingot is sliced in a direction normal to the axis of the ingot to produce thin wafers. These wafers are then subjected to a lapping process to planarize the front and back surfaces of the wafer and to ensure uniform thickness. Following the lapping process, the surfaces of the wafers may be ground to further reduce surface roughness. The wafers are then etched to remove the mechanical damage created by the sawing, lapping and grinding steps, and to remove any embedded lapping grit. Finally, the etched surfaces of the wafer are polished.

To-date, both acidic and caustic chemical formulations have been utilized for purposes of etching the surface of a silicon wafer. One of the most common acidic etchant formulations comprises a solution of hydrofluoric acid (HF), nitric acid (HNO₃), and water (hereinafter “HNO₃-based etchants”). Caustic solutions typically comprising one or more alkaline hydroxides, such as potassium hydroxide (KOH) or sodium hydroxide (NaOH), and water (hereinafter “OH-based etchants”).

These formulations, however, have disadvantages which compromise their effectiveness or limit their utilization in commercial wafer manufacturing processes. For example, while HNO₃-based etchants are preferred in some instances because they yield a somewhat smooth wafer surface, they are also problematic because they are prone to the formation of unwanted solid-phase chemical species on the etched surface of the wafer, which create stains that inhibit further reaction and produce inconsistent etching results. (See, e.g., D. G. Schimmel et al., “An Examination of the Chemical Staining of Silicon”, J. Electrochem. Soc., Vol. 125, p. 152-155 (1978).) HNO₃-based etchants also react during the etching process to produce toxic gases containing oxides of nitrogen (NOₓ), necessitating the use of safety controls and special disposal procedures. Finally, in order to obtain a sufficiently smooth surface using these etchants, a relatively large amount of silicon must be removed from the wafer surfaces, typically about 10-15 μm from each surface.

Generally speaking, limiting the amount of silicon removed from the wafer surfaces is preferred in order to limit the variation in wafer thickness. Stated another way, Global Backside-referenced Indicated Range (GBIR) typically increases as the amount of silicon removed from the wafer surfaces increases. In this respect, caustic etching solutions are preferred because the amount of silicon removed from the wafer surfaces during downstream processes, relative to the acidic solutions, is much less. For example, caustic etchants typically yield wafers having a ΔGBIR (i.e., change in GBIR, as determined by comparing the GBIR of the wafer before and after etching) value of about 0.1 μm, whereas acidic etchants typically yield wafers having )GBIR values ranging from about 0.5-1.5 μm. A low )GBIR value is important because, as this value increases, more silicon must be removed from the wafer surfaces during the subsequent polishing step in order to ensure the final GBIR is acceptable.

Notwithstanding the foregoing advantages, the hydroxide-based etchants have traditionally not been widely utilized in conventional manufacturing processes because these etchants produce a rougher wafer surface than acid etchants. This rougher surface is visible, having a fish scale appearance due to preferential etching along crystallographic planes. Etchants containing Cr⁶⁺ (such as chromate (CrO4²⁻), dichromate (Cr₂O₇²⁻) or chromium trioxide (CrO₃)), hydrofluoric acid and water have been proposed as an alternative to the above-noted hydroxide and HNO₃-based etchants. Significantly, these chromium oxide-based etchants can achieve a smoothness equivalent to that of the HNO₃-based etchants, while yielding a ΔGBIR similar to that of the caustic etchants (removing only about 2-5 μm from each side of the wafer surfaces).

Although the chromium oxide-based etchants can produce a smooth surface while removing substantially less silicon than the HNO₃-based etchants, it also has a number of disadvantages. For example, due to the hazardous nature of chromium, precautions must be taken to limit environmental and human exposure. More importantly, however, is that unlike the HNO₃-based etchants, chromium oxide-based etchants cannot be reconditioned by the simple addition of fresh reagents. The continuous addition of a chromium oxidizing agent to the etchant solution results in the gradual buildup of chromium salts in the etching bath, which ultimately reduce the oxidant capacity in the bath.

Acid etchants employing the permanganate ion (MnO₄₋) as an oxidizer have previously been reported. (See, e.g., U.S. Pat. Nos. 2,847,287 and 5,445,706.) In particular, hydrofluoric acid etchants employing the permanganate ion as an oxidizer have been reported (See, e.g., U.S. Pat. No. 4,372,803). Experience to-date suggests these etchants are preferred over the noted chromium oxide-based etchants because they provide similar results in terms of the amount of silicon removed and the resulting surface smoothness, while being much safer to handle and utilize in a production environment.

These permanganate-based acid etchants, however, have not been widely utilized in conventional manufacturing processes for a number of reasons. First, these etchants can form stains on the surface of the wafer under certain conditions (see K. S. Nahm et al., “Formation mechanism of stains during Si etching reaction in HF-oxidizing agent-H₂O”, J. Appl. Phys., Vol. 81, No. 5, Mar. 1, 1997, p. 2418-2424), although stain formation is still less likely than when HNO₃-based etchants are employed. Second, such etchants, particularly etchant solutions employing hydrofluoric acid, are not economical because the amount of hydrofluoric acid required to obtain a wafer with a specular surface is far in excess of the amount required by the stoichiometry of the etching reaction (i.e. stripping of the silicon oxide from the wafer surface). The primary disadvantage, however, is that much like the chromium oxide-based etchants and unlike the HNO₃-based etchants, a permanganate-based etchant results in the build-up of insoluble reaction byproducts (e.g. MnO₂). The build up of these insoluble byproducts on the surface reduces the ability of the bath to contact and oxidize the surface. But more importantly, the reaction byproducts can produce inconsistent etching results by precipitating non-uniformly out of solution and depositing on the wafer surface. These precipitated compounds tend to mask the wafer surface from the etching action and results in a non-uniform surface.

In an attempt to overcome the problems associated with these insoluble byproducts resulting from the use of permanganate-based acid etchants, WO 00/72368 discloses a hydrofluoric acid and permanganate etching solution that, unlike prior permanganate based etchants, employs the use of a surfactant. The addition of surfactant results in a somewhat more uniform wafer surface by reducing adhesion of precipitated compounds to the silicon, and reducing adhesion between particles of precipitated compounds. This etching solution, however, is not economical because to achieve wafer surfaces with a specular appearance it requires approximately 130 times more hydrofluoric acid than the amount required by the stoichiometry of the etching reaction.

Accordingly, in view of the forgoing, a need continues to exist for a chemical etchant that can be safely used in the commercial production of silicon wafers, that consistently produces a substantially smooth wafer surface without excessive removal of silicon or staining of the wafer surface, and that is economically practical.

### SUMMARY OF THE INVENTION

Among the objects of the present invention may be noted the provision of a process for etching the surface of a silicon wafer; the provision of such a process wherein the etchant solution employed provides improved safety; the provision of such a process wherein the etching solution has improved stability; the provision of such a process that is economical; the provision of such a process wherein the surfaces of the silicon wafer are not stained; the provision of such a process wherein micro-etching of the wafer surface may be achieved; and, the provision of a process wherein such a solution may be utilized to consistently obtain a wafer surface with improved gloss and smoothness.

Other objects and features will be in part apparent and in part pointed out hereinafter.

### BRIEF DESCRIPTION OF THE DRAWINGS

FIG. 1 is a photograph of a Nomarski image of a silicon wafer surface etched in a permanganate etching solution to which a surfactant was added.

FIG. 2 is a photograph of a Nomarski image of a silicon wafer surface etched in a permanganate etching solution having the same composition as that used to etch the wafer of FIG. 1, without surfactant being added.

### DETAILED DESCRIPTION OF THE INVENTION

Mechanical damage to the surfaces of a semiconductor wafer, such as a single crystal silicon wafer, resulting from slicing, lapping and grinding is typically removed by chemical etching. In accordance with the process of the present invention, the surface of the wafer is etched with an aqueous solution comprising hydrofluoric acid (HF), an oxidizing agent capable of forming permanganate ions, and a non-oxidizable acid other than hydrofluoric acid. More preferably, the etching solution will also include a surfactant. The etching process of the present invention, when employed with the parameters detailed herein, consistently yields a wafer surface having improved gloss and smoothness.

The basic etching process of the present invention is illustrated by Equations (1) and (2), wherein potassium permanganate is employed as the oxidizing agent. As shown in these Equations, the permanganate ion and HF are the components of the etching solution responsible for silicon removal from the wafer surface. Without being held to any particular theory, it is generally believed that etching proceeds with the potassium permanganate (KMnO₄), or rather permanganate ion (MnO₄⁻), oxidation of silicon (Si) on the wafer surface to form silicon dioxide (SiO₂) (Equation 1). The hydrofluoric acid (HF) then attacks the silicon dioxide resulting in its removal from the wafer surface (Equation 2). The active etching species in this solution is HF as opposed to F⁻.

4KMnO₄+4H⁺+3Si→4MnO₂(_{S})+3SiO₂+4K⁺ (1)

SiO₂+6HF→H₂SiF₆+2H₂O (2)

Typically, any oxidizing agent capable of forming permanganate ions (MnO₄⁻) in solution is suitable for the present invention. Preferably, however, the oxidizing agent employed will be potassium permanganate (KMnO₄) or sodium permanganate (NaMnO₄) because these agents are relatively inexpensive and safe to handle in a production environment.

Ideally, the etchant solution would require hydrofluoric acid only in stoichiometric amounts, or only the amount needed to dissolve all the silicon dioxide that the reaction in Equation (2) above can produce. As previously indicated, however, a known limitation of etchant solutions employing hydrofluoric acid and permanganate ions is that typically the amount of hydrofluoric acid required to obtain a wafer with a specular surface is far in excess of the amount required by stoichiometry. Without being bound to any particular theory, it is generally believed that the need for this excess is in part three-fold. First, as stated above, HF, as opposed to F⁻, is the active etching agent and therefore hydrofluoric acid preferably remains protonated for etching to proceed. Accordingly, one function of this excess is to maintain a low enough pH of the etching solution so that substantially all the hydrofluoric acid remains protonated. Second, experience to-date has shown that hydrofluoric acid in excess of the stochiometric amount is necessary, at some level, in order to ensure adequate wafer surface quality (described in more detail below). Thirdly, the low pH creates an electrolyte sufficiently concentrated to cause certain surfactant molecules to aggregate in a form appropriate to wet silicon, and wet the insoluble by-products of the etching reaction.

The present invention solves the first of the above mentioned problems, namely maintaining a low etching solution pH, by adding a non-oxidizable acid other than hydrofluoric acid to the solution in addition to the oxidizing agent and hydrofluoric acid. This non-oxidizable acid is added to the etching solution in an amount necessary to maintain the pH between about 0.04 to about 1.4. Still more preferably the pH of the etching solution is maintained at approximately 0.4. At this pH, substantially all of the hydrofluoric acid remains protonated. And more importantly, with the addition of this non-oxidizable acid, the amount of hydrofluoric acid used in the etching solution of the present invention is reduced by approximately 20 fold relative to the amount of hydrofluoric acid employed in prior hydrofluoric acid/permanganate etching solutions (See, e.g. WO 00/72368).

Any per-acid or per-acid salt that is compatible with the oxidizing agent and other operating parameters (e.g. temperature) may be used as the non-oxidizable acid. Typically, however, only monovalent cations are utilized in the acid salts, such as sodium, potassium, lithium, and hydrogen. The per-acid or per-acid salt is preferably selected from sulfuric acid, sodium persulfate, potassium persulfate, and lithium persulfate.

The aqueous etching solution, accordingly, comprises an oxidizing agent, hydrofluoric acid, and a non-oxidizable acid. In one preferred embodiment, hydrofluoric acid and the oxidizing agent are added to the etching solution in stoichiometric amounts, wherein the amount added varies depending upon the amount of silicon to be removed from the wafer surface. Typically, the aqueous etching solution comprises about 1 to about 2 moles of the oxidizing agent and about 10 to about 50 moles of hydrofluoric acid for each mole of silicon to be removed from the wafer's surface. Still more preferably, the aqueous etching solution comprises about 4/3 moles of the oxidizing agent and about 29 to about 38 moles of hydrofluoric acid for each mole of silicon to be removed from the wafer's surface. Stated another way, the etching solution generally comprises a molar ratio of hydrofluoric acid to oxidizing agent between about 17:1 to about 30:1. More preferably, the molar ratio of hydrofluoric acid to oxidizing agent is between about 20:1 to about 25:1. However, it is to be understood that the concentration of hydrofluoric acid and the oxidizing agent in the present aqueous etching solution may be other than that herein described without departing from the scope of the present invention.

The non-oxidizable acid, on the other hand, is added in part, as stated above, to control the pH of the etching solution and therefore is not added in stoichiometric amounts. Accordingly, the non-oxidizable acid is typically added to the etching solution at a concentration between about 0.04 to about 0.60 molar. Still more preferably, the non-oxidizable acid is added to the etching solution at a concentration between about 0.20 to about 0.60 molar. Even more preferably, the non-oxidizable acid is added to the etching solution at a concentration of about 0.40 molar.

Usually, the hydrofluoric acid, the non-oxidizable acid and oxidizing agent are dissolved in water forming an aqueous HF solution, an aqueous non-oxidizable acid solution and an aqueous oxidizing agent solution. For example, a typical aqueous HF solution will consist essentially of water and about 50 weight percent hydrofluoric acid, whereas the oxidizing agent and non-oxidizable acid are generally added to the etching solution as a 1 N aqueous solution. The solutions are then mixed to form an etching solution with the desired composition.

Yet another known limitation of etchant solutions employing the oxidizing agents of the present invention, as stated above, is the generation of insoluble reaction byproducts, such as MnO₂. These insoluble reaction byproducts are problematic because they tightly adhere to the wafer surface. The wafer surface covered by these insoluble byproducts is then masked from the etching action and results in a non-uniform surface.

Referring now to Equations (3) and (4), the problem associated with reaction byproducts will be further described wherein potassium permanganate is employed as the oxidizing agent. Without being held to any particular theory, as stated above, it is generally believed that etching proceeds with the permanganate ion oxidation of silicon on the wafer surface to form silicon dioxide. The silicon dioxide is then dissolved by hydrofluoric acid. This overall process is illustrated by Equation (3) and is ideal because the reaction byproducts are completely soluble and therefore do not mask the wafer surface. In addition, the reaction illustrated by Equation (3) is also ideal because all available electrons are consumed from the permanganate ion for oxidation of silicon to silicon dioxide. But as shown in Equation (4), MnO₂ is a stable reaction intermediate. In addition, Mn²⁺ will always disproportionate with MnO₄⁻ to form MnO₂. Accordingly, MnO₂ will always be present, at some level, in the etchant solutions employing permanganate ions.

4MnO₄⁻+32H⁺+30F⁻+5Si→5SiF₆⁻²+4Mn²⁺+16H₂O (3)

4MnO₄⁻+16H⁺+18F⁻+3Si→3SiF₆⁻²+4MnO₂(_{S})+8H₂O (4)

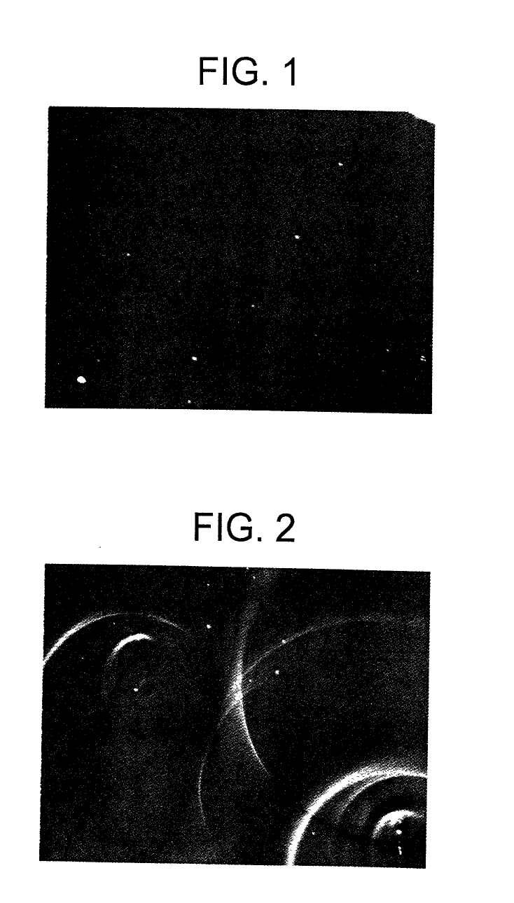

The present invention, in one embodiment, diminishes the impact of these insoluble reaction byproducts by adding a surfactant to the etching solution. For example, referring now to FIGS. 1 and 2 (which are photographs of portions of the surfaces of two wafer, reproduced by Nomarski imaging by means standard in the art), it can be observed that the surface of the wafer in FIG. 2 (which was etched in a solution without a surfactant) clearly has circular or semicircular imprints, left behind by bubbles present in the solution. These bubbles tend to mask the wafer surface in the same manner as MnO₂. In contrast, it can be observed that the surface of the wafer in FIG. 1 (which was etched in a solution comprising a surfactant) does not have these imprints. Without being held to any particular theory, it is generally believed that the surfactant acts as a wetting agent, reducing the surface tension of the aqueous solution on the surface of the wafer and thus preventing MnO₂ from adhering to the wafer surface. Furthermore, it is believed that the surfactant solubalizes MnO₂ produced by the etching reaction and thus prevents it from adhering to the wafer surface. Accordingly, the addition of surfactant to the etching solution results in a more uniform wafer surface and thus provides more consistent etching results.

Any surfactant that is stable in the presence of the oxidizing agent of this invention can be added to the etching solution. For example, a potassium fluoroalkyl carboxylate surfactant sold under the trade designation FC-129 (commercially available from 3M Corporation; St. Paul, Minn.) can be added to the etching solution. Experience to-date, however, suggests that a smoother, more uniformly etched surface may be obtained if the surfactant is derived from sulfonic acids or carboxylic acids. These surfactants, for example, include fluoroalkyl sulfonate surfactants, such as ammonium perfluoroalkyl sulfonate and potassium perfluoroalkyl sulfonate (sold under the respective trade designations FC-93 and FC-95; commercially available from 3M Corporation; St. Paul, Minn.) and mono-valent salts of deodecyl sulfate, such as sodium dodecyl sulfate.

When added to the etching solution, generally speaking a quantity of surfactant will be used which is sufficient to prevent the adherence of insoluble reaction byproducts on the surfaces of the wafer. As further described in the Examples below, wafers may be analyzed in a way which allows for the clear detection of imprints left by these insoluble byproducts which adhere to the wafer surfaces.

More generally, however, it is useful to define the concentration of surfactant needed in terms of the surfactant's critical micelle concentration. The critical micelle concentration is the concentration of surfactant where disperse surfactant aggregates form in solution. Below the critical micelle concentration, the surfactant molecules, rather than forming dispersed aggregates, simply precipitate out of solution. It is thus, above the critical micelle concentration wherein surfactants are effective in the manner described above (e.g. dispersing the MnO₂) for preventing adsorption of insoluble products to the wafer surface. Each surfactant has its own critical micelle concentration and this concentration generally cannot be reliably predicted. The critical micelle concentration, accordingly, is preferably determined experimentally by any means generally known in the art. Typically, however, the aqueous etching solution comprises a surfactant concentration that is about equal to about 8 times greater than the surfactant's critical micelle concentration. For example, the surfactant potassium perfluoroalkyl sulfonate (FC95) a concentration between about 0.80 to about 1.70 grams per liter is added to the etching solution because this concentration is about equal to about 8 times greater than the surfactant's critical micelle concentration. It is to be understood, however, that the concentration of surfactant in the present aqueous etching solution may be other than that herein described without departing from the scope of the present invention.

In yet another embodiment, the current invention minimizes the impact of these insoluble reaction byproducts by employing the use of acoustic assistance (e.g. ultra or mega sound). Acoustic assistance, as utilized here, generally means the use of high frequency sound to change the flow of fluid near the wafer surface so that the adherence of insoluble products to the wafer surface is significantly diminished. This adherence is decreased by employing acoustic assistance, it is generally believed, because a non-linear effect known as “acoustic streaming” occurs when the etching solution is subjected to ultrasound greater than approximately 140 kilohertz. The effect of acoustic streaming, accordingly, is to decrease the hydrodynamic boundary layer between the wafer and the etching solution, which allows faster diffusion of products and reactants near the wafer surface. In addition, ultrasound of sufficient intensity is known to remove particles from surfaces, hence its myriad applications in the field of surface cleaning.

Any technique generally known in the art may be utilized to apply ultra sound to the etching process. But preferably the ultra sound is applied using piezoelectric transducers bonded to the wall of the process chamber or in the fluid application device. Typically, the ultra sound is applied in a range between about 140 to about 2000 kilohertz using a power density of approximately 10 watts per liter. More preferably, however, the range is between about 500 to about 1500 kilohertz.

Furthermore, another embodiment diminishes the impact of these insoluble reaction byproducts by adding hydrogen peroxide (H₂O₂) or oxalate (H₂C₂O₄) to the etching solution when substantially all of the permanganate ions in the solution have been converted to MnO₂. Both of these compounds convert insoluble MnO₂ to the soluble product Mn²⁺. Typically, hydrogen peroxide or oxalate are added to a depleted etching solution at the end of the etching process in amounts that are approximately 10% in excess of the stoichiometric amount needed to react away all of the MnO₂.

In order to minimize the impact of MnO₂ adherence to the wafer surface, it is noted that prior etching solutions comprising permanganate ions and hydrofluoric acid, as stated above, have added hydrofluoric acid in amounts greatly exceeding the stoichiometric amount needed for etching. Excess hydrofluoric acid accomplishes this result, in part, because it converts insoluble MnO₂ to soluble MnF₄, which because it is soluble, does not adhere to the wafer surface. The present invention decreases the amount of hydrofluoric acid added to the etching solution, as stated above, by a factor of 20 relative to prior etching solution employing permanganate ions and hydrofluoric acid (See, e.g., WO 00/72368). This decrease is possible by utilizing the factors discussed above to minimize the impact of insoluble reaction byproducts (e.g. the use of a surfactant, acoustic assistance, oxalate, and hydrogen peroxide). Significantly, this decrease in the amount of hydrofluoric acid added to the etching solution makes the etching process of the present invention more economical relative to prior etching solutions.

Another embodiment of the invention, is the use of hydrogen peroxide to clean the silicon of residual Manganese, by subsequently cleaning the wafer in a hot solution of ammonia, hydrogen peroxide and water, in proportions of 1:1:5 of the concentrated reagents at 70° C. Experience to-date has shown that the use of the etching solution of the present invention results in the development of a film on the etched wafers. The use of this cleaning composition, however, removes this film. It is to be understood, however, that the concentration of the various components of the cleaning composition may be other than that described without departing from the scope of the present invention. The use of this cleaning composition, however, removes this film.

As previously noted, another known limitation of etchant solutions employing the oxidizing agents of the present invention is the inability to regenerate or recondition these solutions. The introduction of additional reagents results in the build-up of salts in the etching bath which interfere with the etching process. This interference may be due to the salts becoming deposited on the wafer surface, thus acting as a mask and causing non-uniform results, or the salts may act to reduce the oxidizing capacity of the reagents.

Without being held to any particular theory, experience to-date suggests that the etchants of the present invention may be regenerated or reconditioned by restoring the oxidation state of the reagents, or more specifically the ions, responsible for oxidizing the surface of the silicon wafer as part of the etching process. The methods to regenerate or recondition the oxidizing agents of the present invention by restoring the oxidation state is fully described in WO 0072368, which is incorporated herein by reference in its entirety.

Another embodiment of the invention alleviates the problem associated with reconditioning, as described above, by the addition of hydrochloric acid to the etching solution in a process known as “HCl Spiking”. Hydrochloric acid converts MnO₂ to MnCl₆²⁻. This chloride compound is soluble and therefore can react with the wafer surface to oxidize silicon. While HCl Spiking does not recondition permanganate ions, it does allow the reaction to go to thermodynamic completion because it provides a means to extract further oxidation capacity from a different manganese species (i.e. MnCl₆²⁻).

HCl Spiking, however, is preferably only employed when substantially all of the permanganate has reacted because permanganate oxidizes HCl to chlorine gas, which is highly toxic. Typically, the amount of HCl added to the etching solution will be approximately 10% in excess of the stoichiometric amount required to convert substantially all of the MnO₂ in the etching solution to MnCl₆²⁻, thereby extending the oxidative capacity of the etching solution.

The process of the present invention is typically performed at a temperature greater than 45° C. More preferably, the process is performed at a temperature between about 45 to about 70° C. Still more preferably, the process is performed at a temperature between about 50 to about 60° C. Experience to-date suggests temperatures within this range generally enhance the wetting properties of the surfactant and facilitate reasonable etch rates for the process detailed herein.

The etchant solution of the present invention may be employed in a number of different techniques common in the art in order to etch the wafer surface. For example, one technique, referred to as spin etching, is disclosed in U.S. Pat. No. 4,903,717. The spin etching technique comprises rotating the wafer while a continuous stream of etchant is applied to the top of the wafer. Another technique is spray etching, wherein a continuous spray of etchant is applied to the wafer surface.

Preferably, however, the etching process of the present invention comprises partially, and more preferably fully, immersing the wafer into a bath of the etchant solution. (See, e.g., U.S. Pat. No. 5,340,437.) Although one wafer at a time may be immersed in the solution, preferably a number of wafers (e.g., 25 or more) will be assembled in a cassette, or wafer carrier, and immersed at the same time in the solution. When such a carrier is used, however, certain portions of each stationary wafer will be in constant contact with the carrier, resulting in non-uniform etching across the surface of each wafer. To eliminate this problem and provide a more uniform result over the entire wafer surface, the wafers are preferably rotated while immersed in the etchant solution.

Furthermore, because the wafers are closely spaced, typically between about 4 mm to about 7 mm apart, rotation of the wafers tends to produce a rigid-body rotation of the liquid between the wafers. As a result, stagnation of the etchant solution between the wafers typically occurs. Stagnation is a concern because acid etching of silicon is believed to be at least in part dependent upon the mass transfer rate at the silicon-etchant interface. As the etching reaction proceeds, the concentrations of acid and oxidizing agent decrease at the interface and the concentration of reaction products increases. Accordingly, non-uniform etching results may be obtained not only across the surface of a given wafer, but also from one wafer surface to the next within the set of wafers in the wafer carrier.

In order to produce uniformly etched wafers and to ensure consistent results from one set of wafers to the next, it is preferred that the etchant solution be continuously mixed or agitated for the duration of the etching process. Bath agitation or mixing may be achieved by means known in the art, such as by employing ultrasonic agitation, stirring devices and pumps. Preferable, however, agitation is achieved by passing or “bubbling” a gas through the etchant solution (see, e.g., U.S. Pat. No. 5,340,437). Generally, any gas which will not react with the wafer surface may be employed, including elemental gases (e.g., hydrogen, nitrogen, oxygen), noble gases (e.g., helium or argon) or compound gases (e.g., carbon dioxide).

It is to be noted that, in addition to the gas bubbles introduced into the etchant solution as a result of gas agitation, gas bubbles may also be formed via the etching reaction itself. More specifically, as the etchants of the present process react with the wafer surface, hydrogen gas evolves, creating hydrogen bubbles in the etching bath. These bubbles tend to adhere to the wafer surface and may interfere with the action of the etchant, resulting in non-uniform etching and possibly surface staining. (See, e.g., Kulkarni et al., AIChE Conference, Paper 124f, AIChE Conference, Los Angeles (1997).) The effects of these bubbles can be minimized, however, by the addition of a surfactant to the etchant solution. The parameters for adding surfactant to the etching solution have been fully described above.

The process of the present invention can be used to treat a wide variety of incoming semiconductor wafers. However, the etching process of this invention is preferably performed after mechanical operations upon the wafer, such as lapping and grinding, are complete. Lapping operations are performed after slicing to further flatten the wafer surface. Preferably an incoming wafer will have a GBIR value of about 1 μm. Grinding is generally performed to reduce the roughness of the lapped wafer surface. Typically, a ground wafer has a surface roughness of about 0.02 to about 0.05 μm Ra. It is to be noted, however, that the process of the present invention may be performed on wafers having other than the GBIR and roughness values as herein described without departing from the scope of the present invention.

Prior to etching the incoming wafer, it is preferred that the wafer be pre-treated, ensuring that one or more surfaces of the wafer is clean, passivated, and free of lapping and grinding residue. This pre-treatment can be accomplished by any means known in the art (see, e.g., U.S. Pat. No. 5,593,505).

In a preferred embodiment, the etching process of the present invention provides a means to precisely control the amount of silicon removed from the wafer surface because the etching reagents (i.e. permanganate and hydrofluoric acid) are added in stoichiometric amounts, and these amounts are not maintained at a constant composition throughout the etching process. Accordingly, the amount of silicon removed from the wafer surface is controlled by the amount of permanganate and hydrofluoric acid added to the etching solution. Without being held to any particular theory, it is generally believed that the present invention enables a level of surface roughness to be obtained which is at least equivalent to that of nitric acid-based etchants, while removing less silicon from the wafer surface, due to the slower etching rate. The end result is a wafer surface with a specular appearance.

Generally, the process of the invention involves contacting the wafer surface with the aqueous etchant solution for the amount of time required to obtain the desired removal of silicon from the wafer surface. More preferably, the wafer is contacted with the etchant solution for about 1 to about 20 minutes. Even more preferably, the wafer is contacted with the etchant solution for about 1 to about 10 minutes. Still more preferably, the wafer is contacted with the etchant solution for about 2 to about 5 minutes.

While the present etching process may be utilized to obtain a surface roughness which is essentially the same as a nitric acid-based etchants, experimental evidence to-date suggest the present process may be optimized to obtained a surface roughness of less than about 0.08 μm Ra, preferably less than about 0.05 μm Ra, and most preferably less than about 0.02 μm RA. In comparison, a typical mechanochemical polishing process, wherein a polishing pad and polishing slurry are involved (see, e.g., U.S. Pat. No. 5,377,451), produces a wafer with a surface roughness of about 0.001 μm Ra. However, such standard polish processes remove about 10-15 μm silicon from the wafer surface. Accordingly, it is believed that the present “micro-etching” process (i.e., a process which provides a smooth wafer surface with minimal silicon removal) may be a potential alternative to standard mechanochemical polishing processes. More specifically, it is generally believed that a mechanochemical process utilizing a slurry comprising the permanganate-based etchants of the present invention and standard particulate matter could be employed to produce a finished wafer in less time and with less silicon removed than when standard acid etching and polishing operations are performed separately. The permanganate-based etchants could be applied as a slurry to a polishing pad in accordance with standard polishing processes. This integration of acid etching and mechanical polishing would attain a low degree of surface roughness through the combined chemical effect of the present etchants and mechanical effect of the particulate/polishing pad.

However, it is to be noted that if the present process were to be utilized as a replacement for standard polishing techniques, improvements in existing polishing pads would likely be required. Such improvements would be needed if the present process were to be so utilized for commercially practical periods of time because standard acid-resistant pads will not typically withstand the particulate abrasion which occurs on the pad surfaces for a period of time sufficient to make the process economically feasible. Likewise, pads capable of withstanding the abrasion which occurs typically cannot resist the extremely corrosive hydrofluoric acid environment. Accordingly, until polishing pad technology can produce pads with sufficient acid and abrasion resistance, the benefits of integrating the etchants of the present invention with the polishing step cannot be fully realized.

### EXAMPLES

10 Ω-cm P− Wafers with Soft Backside Damage.

The material used for the following experiments was MEMC type SAS-YX-33F. This is a 10 Ω-cm boron doped P− wafer with soft-backside damage. The front side was polished.

A solution was prepared containing 1.20 gm of FC95, 3.6 ml of IPA, 6.62 gm of KMnO₄, and 6.51 ml of HF; diluted to 600 ml. The temperature was 52±4° C. A 1.9234 gm wafer was introduced and etched for 300 minutes in the presence of ultrasound, removing 0.2346 grams. The initial removal rate was 0.37 μm/minute. The surface finish was shiny with some spots of erosion due to the static sonic field.

A solution was prepared containing 4.74 gm of KMnO₄, 20.76 ml of HF, 13.3 ml of H₂SO₄, 1.0 gm of FC95, diluted to 600 ml. The temperature was 50±1° C. A 2.2384 gm wafer was introduced and etched for 1212 minutes, removing 0.9178 grams. The initial removal rate was 1.20 μm/minute. The surface had a mirror finish with no interference colors after 0.6349 gm were removed. It was difficult to tell apart the two sides using the naked eye. On completion the surface displayed some color, a gold tint.

A solution was prepared containing 4.74 gm of KMnO₄, 20.76 ml of HF, 13.3 ml of H₂SO₄, and 1.0 gm of FC95 diluted to 600 ml. The temperature was 55±1° C. A 2.0514 gm wafer was introduced and etched for 286 minutes, removing 0.5968 grams. The initial removal rate was 1.34 μm/minute. The surface had a mirror finish with no interference colors. It was difficult to tell apart the two sides using the naked eye. The surface developed green interference colors sometime before etching for 1232 minutes. After 1232 minutes, the weight loss was 0.8336 grams.

A solution was prepared containing 4.75 gm of KMnO₄, 20.76 ml of HF, 13.33 ml of H₂SO₄, 0.999 gm of FC95, diluted to 600 ml. The temperature was 60±1° C. A 2.0507 gm wafer was introduced and etched for 349 minutes, removing 0.5909 grams. The initial removal rate was 1.51 μm/minute. The surface was shiny on both sides of the wafer, it being difficult to tell one side from the other with the naked eye. The surface developed green interference colors sometime before etching for 1290 minutes. After 1290 minutes, the weight loss was 0.8070 grams. A 1:1:5 SC-1 solution at 70° C. stripped the film in a few minutes, to reveal a mirror finish.

A solution was prepared containing 4.74 gm of KMnO₄, 20.76 ml of HF, 13.33 ml of H₂SO₄, 1.01 gm of FC95, diluted to 600 ml. The temperature was 65±1° C. A 2.1197 gm wafer was introduced and etched for 306 minutes, removing 0.5736 grams. The initial removal rate was 1.80 μm/minute. The surface was shiny on both sides of the wafer, it being difficult to tell one side from the other with the naked eye. The surface developed green interference colors sometime before etching for 1224 minutes. After 1224 minutes, the weight loss was 0.8291 grams.

A solution was prepared containing 4.74 gm of KMnO₄, 41.5 ml of HF, 13.33 ml of H₂SO₄, 1.0 gm of FC95, diluted to 600 ml. The temperature was 60±1° C. A 2.0207 gm wafer was introduced and etched for 146 minutes, removing 0.6052 grams. The initial removal rate was 3.31 μm/minute. The surface was shiny.

A solution was prepared containing 4.75 gm of KMnO₄, 31.1 ml of HF, 13.33 ml of H₂SO₄, 1.0 gm of FC95, diluted to 600 ml. The temperature was 60±1° C. A 2.1492 gm wafer was introduced and etched for 192 minutes, removing 0.6487 grams. The initial removal rate was 2.70 μm/minute. The surface was shiny.

A solution was prepared containing 2.3717 gm of KMnO₄, 20.76 ml of HF, 13.33 ml of H₂SO₄, 1.00 gm of FC95, diluted to 600 ml. The temperature was 60±1° C. A 2.0873 gm wafer was introduced and etched for 208 minutes, removing 0.3275 grams. The initial removal rate was 1.64 μm/minute. The surface was shiny on both sides of the wafer.

A solution was prepared containing 4.74 gm of KMnO₄, 21.3 ml of HF, 13.33 ml of H₂SO₄, 0.500 gm of FC95, diluted to 600 ml. The temperature was 60±1° C. A 2.2163 gm wafer was introduced and etched for 238 minutes, removing 0.6086 grams. The initial removal rate was 1.68 μm/minute. A glossy mirror finish was revealed.

A solution was prepared containing 4.745 gm of KMnO₄, 21.3 ml of HF, 13.33 ml of H₂SO₄, 1.00 gm of FC 95, diluted to 600 ml. The temperature was 60±1° C. A 1.9043 gm wafer was introduced and etched for 240 minutes, removing 0.6037 grams. A glossy finish was revealed. The initial removal rate was 1.51 μm/minute.

N− Wafers

The material used for the following experiments was MEMC type RWM-YY-59B. This is a Phosphorus doped N− wafer (0.5 to 1200 Ω-cm). Both sides were polished.

A solution was prepared containing 4.74 gm of KMnO₄, 21.3 ml of HF, 13.3 ml of H₂SO₄, and 1.00 gm of FC95 diluted to 600 ml. The temperature was 60±1° C. A 2.1640 gm wafer was introduced and etched for 249 minutes, removing 0.6096 grams. A slight hazy appearance developed after 0.2355 grams were removed. The surface gloss was restored on removing 0.6002 grams. The initial removal rate was 1.53 mm/minute.

P+ Wafers

The material used for the following experiments was MEMC type RES-YX-Q8B. This is a Boron doped P+ wafer (0.005 W-cm). Both sides were polished.

A solution was prepared containing 4.74 gm of KMnO₄, 21.3 ml of HF, 13.3 ml of H₂SO₄, and 1.00 gm of FC95 diluted to 600 ml. The temperature was 60±1° C. A 2.1816 gm wafer was introduced and etched for 289 minutes, removing 0.6058 grams. A slight hazy appearance developed after 0.3896 grams were removed. The surface gloss was restored on removing 0.5373 grams. Etching to 1266 minutes removed 0.8232 grams; developing interference colors that were indistinct when compared to those on P− material. The initial removal rate was 1.16 mm/minute.

In view of the above, it will be seen that the several objects of the invention are achieved. As various changes could be made in the above compositions and processes without departing from the scope of the invention, it is intended that all matter contained in the above description be interpreted as illustrative and not in a limiting sense.

What is claimed is:

1. An etching process for removing silicon from a surface of a silicon wafer, the process comprising immersing the silicon wafer in a bath, the bath comprising an aqueous etch solution, the etch solution comprising hydrofluoric acid, an oxidizing agent capable of forming permanganate ions, and a non-oxidizable acid other than hydrofluoric acid, wherein the oxidizing agent is reduced during removal of silicon from the wafer's surface.

2. The process of claim 1 wherein the oxidizing agent is potassium permanganate or sodium permanganate.

3. The process of claim 1 wherein the etch solution further comprises a surfactant.

4. The process of claim 3 wherein the surfactant is derived from sulfonic acids or carboxylic acids.

5. The process of claim 4 wherein the surfactant is selected from the group consisting of ammonium perfluoroalkyl sulfonate, potassium perfluoroalkyl sulfonate, and sodium dodecylsulfate.

6. The process of claim 3 wherein the surfactant concentration is about equal to about 8 times greater than the surfactant's critical micelle concentration.

7. The process of claim 3 wherein the surfactant concentration is approximately equal to the surfactant's critical micelle concentration.

8. The process of claim 3 wherein the etch solution comprises about 0.04 to about 0.60 molar of the non-oxidizable acid.

9. The process of claim 3 wherein the etch solution comprises about 0.20 to about 0.60 molar of the non-oxidizable acid.

10. The process of claim 3 wherein the etch solution comprises approximately 0.40 molar of the non-oxidizable acid.

11. The process of claim 1 wherein the non-oxidizable acid is a per-acid or a per-acid salt.

12. The process of claim 1 wherein the non-oxidizable acid is selected from the group consisting of sulfuric acid, sodium persulfate, potassium persulfate, and lithium persulfate.

13. The process of claim 1 wherein the non-oxidizable acid is sulfuric acid.

14. The process of claim 1 wherein the etch solution comprises a molar ratio of hydrofluoric acid to oxidizing agent between about 17:1 to about 30:1.

15. The process of claim 8 wherein the etch solution comprises a molar ratio of hydrofluoric acid to oxidizing agent between about 17:1 to about 30:1.

16. The process of claim 1 wherein the process is conducted at a temperature between about 45 to about 70° C.

17. The process of claim 1 wherein the process is conducted at a temperature between about 50 to about 60° C.

18. The process of claim 15 wherein the process is conducted at a temperature between about 50 to about 60° C.

19. The process of claim 1 wherein the pH of the etch solution is about 0.04 to about 1.4.

20. The process of claim 1 wherein the pH of the etch solution is about 0.4.

21. The process of claim 1 wherein the etch solution is subjected to acoustic agitation.

22. The process of claim 21 wherein the acoustic agitation is ultrasonic agitation or mega-sound agitation.

23. The process of claim 18 wherein the etch solution is subjected to acoustic agitation.

24. The process of claim 1 further comprising adding H₂O₂ or H₂C₂O₄ to the etch solution when substantially all of the permanganate ions in the etch solution have been converted to MnO₂.

25. The process of claim 24 wherein the amount of H₂O₂ or H₂C₂O₄ added to the etch solution is approximately 10 percent in excess of the stoichiometric amount needed to convert substantially all of the MnO₂ in the etch solution to Mn²⁺.

26. The process of claim 1 further comprising adding hydrochloric acid to the etch solution when substantially all of the permanganate ions in the etch solution have been converted to MnO₂.

27. The process of claim 26 wherein the amount of hydrochloric acid added to the etch solution is approximately 10 percent in excess of the stoichiometric amount needed to convert MnO₂ in the etch solution to MnCl₆.

28. The process of claim 1 wherein the etch rate is about 0.5 to about 5 μm per minute.

29. An aqueous etching solution comprising hydrofluoric acid, an oxidizing agent capable of forming permanganate ions, and a non-oxidizable acid other than hydrofluoric acid.

30. The etch solution of claim 29 wherein the etch solution comprises a molar ratio of hydrofluoric acid to oxidizing agent between about 17:1 to about 30:1.

31. The etch solution of claim 30 wherein the etch solution comprises about 0.04 to about 0.60 molar of the non-oxidizable acid.

32. The etch solution of claim 31 wherein the etch solution further comprises a surfactant.

33. The etch solution of claim 32 wherein the surfactant is derived from sulfonic acids or carboxylic acids.

34. The etch solution of claim 33 wherein the non-oxidizable acid is sulfuric acid.
